(19) United States
(12) Patent Application Publication
(10) Pub. No.: US 2013/0076355 A1
(43) Pub. Date: Mar. 28, 2013

(54) Fast, Low Energy Deposition and Homogeneous T2 Weighted Variable Amplitude PSIF (T2 VAPSIF) Imaging in the Presence of B0inhomogeneities

(71) Applicants: Subashini Srinivasan, Los Angeles, CA (US); Sunil Goraksha Patil, Columbia, MD (US); Wesley David Gilson, Pasadena, MD (US)

(72) Inventors: Subashini Srinivasan, Los Angeles, CA (US); Sunil Goraksha Patil, Columbia, MD (US); Wesley David Gilson, Pasadena, MD (US)

(73) Assignee: Siemens Corporation, Iselin, NJ (US)

(21) Appl. No.: 13/627,023

(22) Filed: Sep. 26, 2012

Related U.S. Application Data
(60) Provisional application No. 61/540,115, filed on Sep. 28, 2011.

(51) Int. Cl. G01R 33/44

(52) U.S. Cl. 324/309

(57) ABSTRACT

A method for acquiring medical images, including: applying, during a first period, a plurality of radio frequency (RF) pulses to an area of interest, wherein the RF pulses applied during the first period are Kaiser-Bessel pulses; applying, during a second period, a plurality of 180 degree RF preparation pulses to the area; applying, during a third period, a plurality of 180 degree RF pulses to the area to acquire a center of a k-space; applying, during a fourth period, a plurality of RF pulses to the area, wherein the RF pulses applied during the fourth period have an angle smaller than the 180 degree RF pulses applied during the third period; applying, during a fifth period, a plurality of constant RF pulses to the area to acquire outer lines of the k-space; and generating an image of the area by using a steady-state free precession echo readout.

### CROSS-REFERENCE TO RELATED APPLICATION

This application claims priority under 35 U.S.C. §119 to U.S. provisional application No. 61/540,115 filed Sep. 28, 2011, the disclosure of which is incorporated by reference herein in its entirety.

### BACKGROUND OF THE INVENTION

1. Technical Field

The present invention relates to imaging techniques for magnetic resonance imaging (MRI).

2. Discussion of the Related Art

In an interventional MRI (e.g., needle biopsies, atrial fibrillation, etc.), interactive, real-time, fast T₂-weighted imaging is desirable. Currently, Half Fourier Acquisition Single shot Turbo spin Echo (HASTE) is the preferred sequence for this purpose. However, HASTE utilizes a series of 180° pulses throughout the acquisition that increase the specific absorption rate (SAR) level. In addition, HASTE suffers from reduced spatial resolution of the shorter T₂ tissues as the signal level decays to zero by the time of acquisition of the outer k-space lines.

Recently, T₂-TIDE (transition into driven equilibrium), a balanced steady-state free precession (SSFP) based imaging sequence with α/2 preparation, was proposed to acquire T₂-weighted imaging with reduced SAR and acquisition duration. T₂-TIDE further improves the spatial resolution of structures with short T₂. However, T₂-TIDE is susceptible to banding artifacts due to off-resonance or B₀ inhomogeneities (e.g., for local air-tissue interfaces and main magnetic field imperfections).

### SUMMARY OF THE INVENTION

The invention disclosed herein, which is termed as T₂-weighted variable amplitude PSIF (T₂VAPSIF) imaging, does not result in banding artifacts due to B₀ inhomogeneities but maintains a shorter acquisition duration, reduced SAR and increased spatial resolution of shorter tissues similar to T₂-TIDE and has T₂ contrast comparable to HASTE.

In an exemplary embodiment of the present invention, there is provided a method for acquiring medical images, the method comprising: applying, during a first period, a plurality of radio frequency (RF) pulses to an area of interest, wherein the RF pulses applied during the first period are Kaiser-Bessel pulses; applying, during a second period, a plurality of 180 degree RF preparation pulses to the area; applying, during a third period, a plurality of 180 degree RF pulses to the area to acquire a center of a k-space; applying, during a fourth period, a plurality of RF pulses to the area, wherein the RF pulses applied during the fourth period have an angle smaller than the 180 degree RF pulses applied during the third period; applying, during a fifth period, a plurality of constant RF pulses to the area to acquire outer lines of the k-space, wherein the RF pulses applied during the fifth period have an angle less than the angle of the RF pulses applied during the fourth period; and generating an image of the area by using a steady-state free precession echo readout.

The image is a magnetic resonance image.

The RF pulses of the first to fifth periods are generated by controlling an RF coil array adapted to produce a plurality of magnetic fields in the area.

The area of interest includes an anatomical part of a human.

The image is T₂ weighted.

The steady-state free precession echo readout begins after the second period.

In an exemplary embodiment of the present invention, there is provided a method for acquiring medical images, the method comprising: applying, during a first period, a plurality of RF pulses to an area of interest, wherein the RF pulses applied during the first period are Kaiser-Bessel pulses; applying, during a second period, a plurality of 180 degree RF pulses to the area to acquire a center of a k-space; applying, during a third period, a plurality of RF pulses to the area, wherein the RF pulses applied during the third period have an angle smaller than the 180 degree RF pulses applied during the second period; applying, during a fourth period, a plurality of constant RF pulses to the area to acquire outer lines of the k-space, wherein the RF pulses applied during the fourth period have an angle less than the angle of the RF pulses applied during the third period; and generating an image of the area by using a steady-state free precession echo readout.

The image is a magnetic resonance image.

The RF pulses of the first to fourth periods are generated by controlling an RF coil array adapted to produce a plurality of magnetic fields in the area.

The area of interest includes an anatomical part of a human.

The image is T₂ weighted.

The steady-state free precession echo readout begins after the first period.

In an exemplary embodiment of the present invention, there is provided a method for acquiring medical images, the method comprising: applying, during a first period, a plurality of RF pulses 10 an area of interest, wherein the RF pulses applied during the first period are linear ramp type pulses; applying, during a second period, a plurality of 180 degree RF pulses to the area to acquire a center of a k-space; applying, during a third period, a plurality of RF pulses to the area, wherein the RF pulses applied during the third period have an angle smaller than the 180 degree RF pulses applied during the second period; applying, during a fourth period, a plurality of constant RF pulses to the area to acquire outer lines of the k-space, wherein the RF pulses applied during the fourth period have an angle less than the angle of the RF pulses applied during the third period; and generating an image of the area by using a steady-state free precession echo readout.

The image is a magnetic resonance image.

The RF pulses of the first to fourth periods are generated by controlling an RF coil array adapted to produce a plurality of magnetic fields in the area.

The area of interest includes an anatomical part of a human.

The image is T₂ weighted.

The steady-state free precession echo readout begins after the first period.

In an exemplary embodiment of the present invention, there is provided a method for acquiring medical images, the method comprising: applying, during a first period, a plurality of RF pulses to an area of interest, wherein the RF pulses applied during the first period are Kaiser-Bessel pulses; applying, during a second period, a plurality of RF pulses to the area, wherein the RF pulses applied during the second period have an angle greater than an angle of the Kaiser-Bessel pulses applied during the first period; applying, during a third period, a plurality of RF pulses to the area, wherein the RF pulses applied during the third period ramp up the angle of the RF pulses applied during the second period to about 180 degrees; applying, during a fourth period, a plurality of 180 degree RF pulses to the area to acquire a center of a k-space; applying, during a fifth period, a plurality of RF pulses to the area, wherein the RF pulses applied during the fifth period have an angle smaller than the 180 degree RF pulses applied during the fourth period; applying, during a sixth period, a plurality of constant RF pulses to the area to acquire outer lines of the k-space, wherein the RF pulses applied during the sixth period have an angle less than the angle of the RF pulses applied during the fifth period; and generating an image of the area by using a steady-state free precession echo readout.

The steady-state free precession echo readout begins after the second period.

### BRIEF DESCRIPTION OF THE DRAWINGS

FIG. 1A is a pulse sequence timing diagram of T₂VAPSIF;

FIG. 1B is a pulse sequence timing diagram of the radio frequency (RF) pulses for T₂VAPSIF and a diagram demonstrating the k-space coverage;

FIG. 2 is a simulation of the transverse magnetization over number of echoes for T₂-TIDE and T₂VAPSIF;

FIG. 3 illustrates phantom images acquired with different sequences;

FIG. 4 is a comparison of the point spread function of TSE, HASTE and T₂VAPSIF;

FIG. 5 shows abdominal images acquired using TSE, HASTE, T₂-TIDE and T₂VAPSIF:

FIG. 6 is a table showing the imaging parameters for FIG. 3;

FIG. 7 is a table showing the imaging parameters for FIG. 5;

FIG. 8 is a pulse sequence timing diagram of TRAPS-based T₂VAPSIF;

FIG. 9 is a simulation of transverse magnetization of TRAPS-based T₂VAPSIF with parameters similar o FIG. 2d;

FIG. 10 shows abdominal images acquired using T₂VAPSIF and TRAPS-based T₂VAPSIF; and

FIG. 11 illustrates a computer system in which an exemplary embodiment of the present invention may be implemented.

### DETAILED DESCRIPTION OF EXEMPLARY EMBODIMENTS

In accordance with an exemplary embodiment of the present invention, T₂-TIDE is optimized by adding a Kaiser Bessel (KB) preparation scheme and combined with SSFP-ECHO (aka PSIF) to reduce B₀ inhomogeneity related artifacts, while maintaining excellent T₂ weighing. As mentioned above, the method according to an exemplary embodiment of the present invention is termed as T₂-weighted variable amplitude PSIF (T₂VAPSIF) imaging.

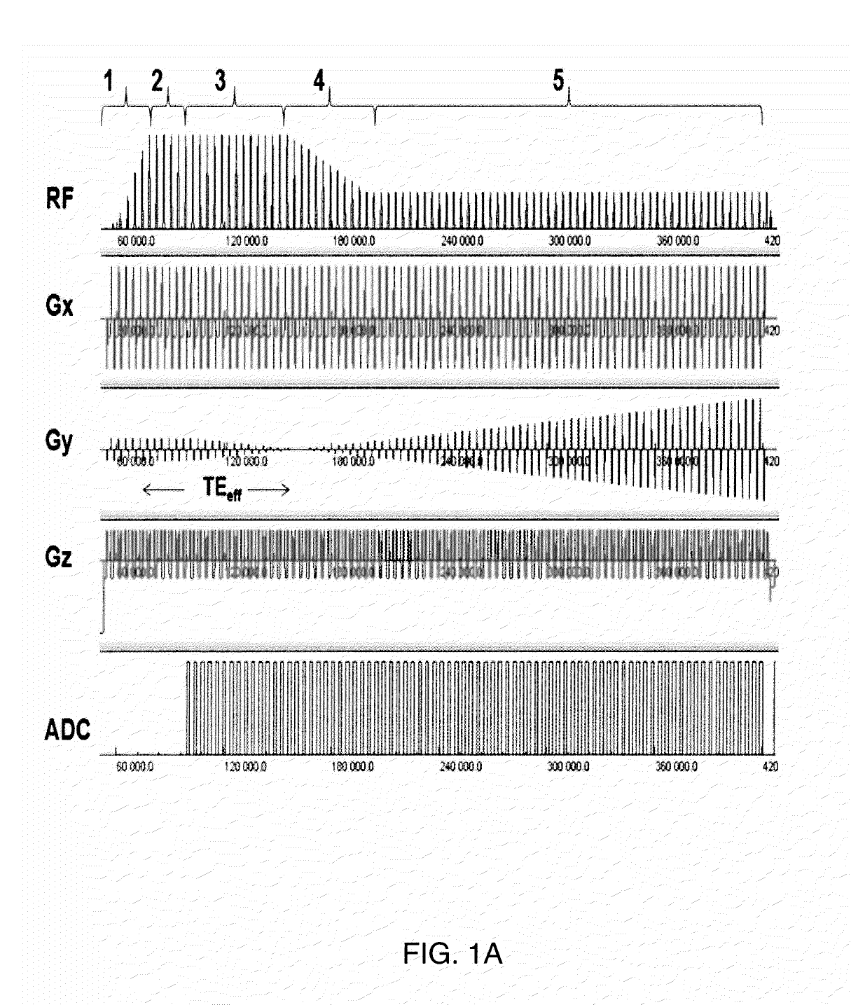

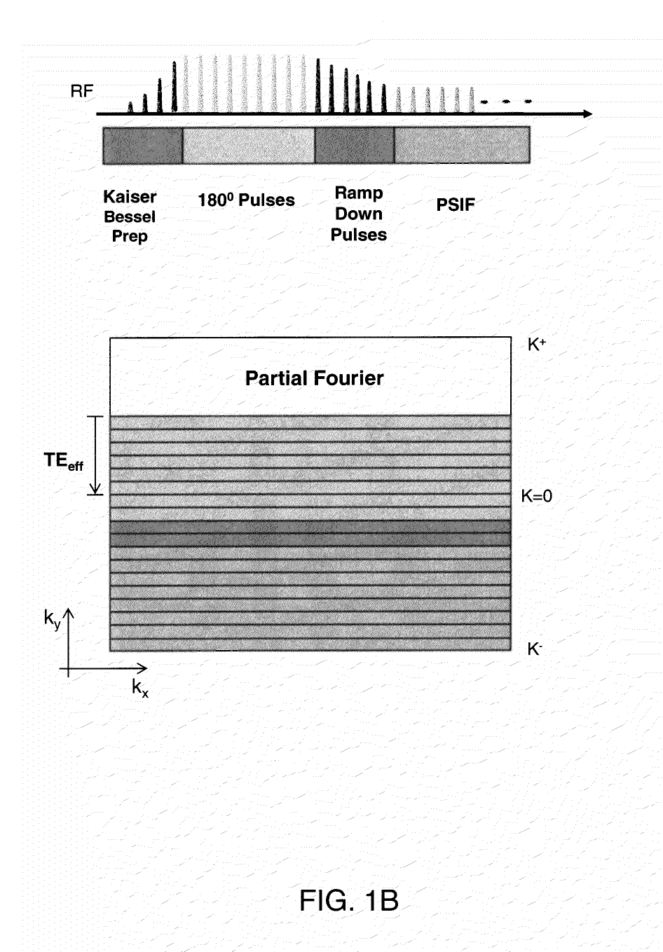

The sequence diagram of T₂VAPSIF depicting the inventive flip angle scheme is shown in FIG. 1A. T₂VAPSIF consists of five blocks of variable flip angles (i.e., blocks 1-5). The first block (1) consists of preparation pulses #prep, for example, KB pulses (#kaiser). KB pulses are described in “Simplified model and stabilization of SSFP sequences,” Patrick Le Roux, Journal of Magnetic Resonance, pp. 23-37, 2003, the disclosure of which is incorporated by reference herein in its entirety. The preparation pulses could also be a liner ramp (#linear) or similar type pulses. The second block (2) is an optional preparation block of 180° pulses (#M), followed by a third block (3) of a set of 180° pulses (#N) during which the center of k-space is acquired. The fourth block (4) is TIDE variable flip angle ramp down pulses (#nTIDE), which cause a smooth transition from 180° to the lower flip angle. The outer k-space lines are acquired in the fifth block (5) of the constant lower flip angle pulses thereby preventing the saturation of the signal and decreasing the SAR level.

In FIG. 1A, the above-described pulses are radio frequency (RF) pulses of the RF row. In FIG. 1A, Gx, Gy, and Gz represent the read, phase and slice encoding gradients. and analog-to-digital converter (ADC) identifies the reading out of data corresponding to the gradients Gx, Gy, and Gz. In FIG. 1A, TE_{eff} is the effective echo time. In FIG. 1A, the data is not read until after the second block (2). In FIG. 1A, data is acquired using an SSFP-ECHO imaging scheme.

FIG. 1B is another view of the T₂VAPSIF sequence diagram shown in FIG. 1A. FIG. 1B clarifies the k-space coverage. In FIG. 1B, TE_{eff} may be chosen by a user on the fly while running the sequence. In order to fill this time, dummy 180 degree pulses (e.g., the ‘optional’ ones discussed above) may be used while ADC is off. After this, ADC is initiated.

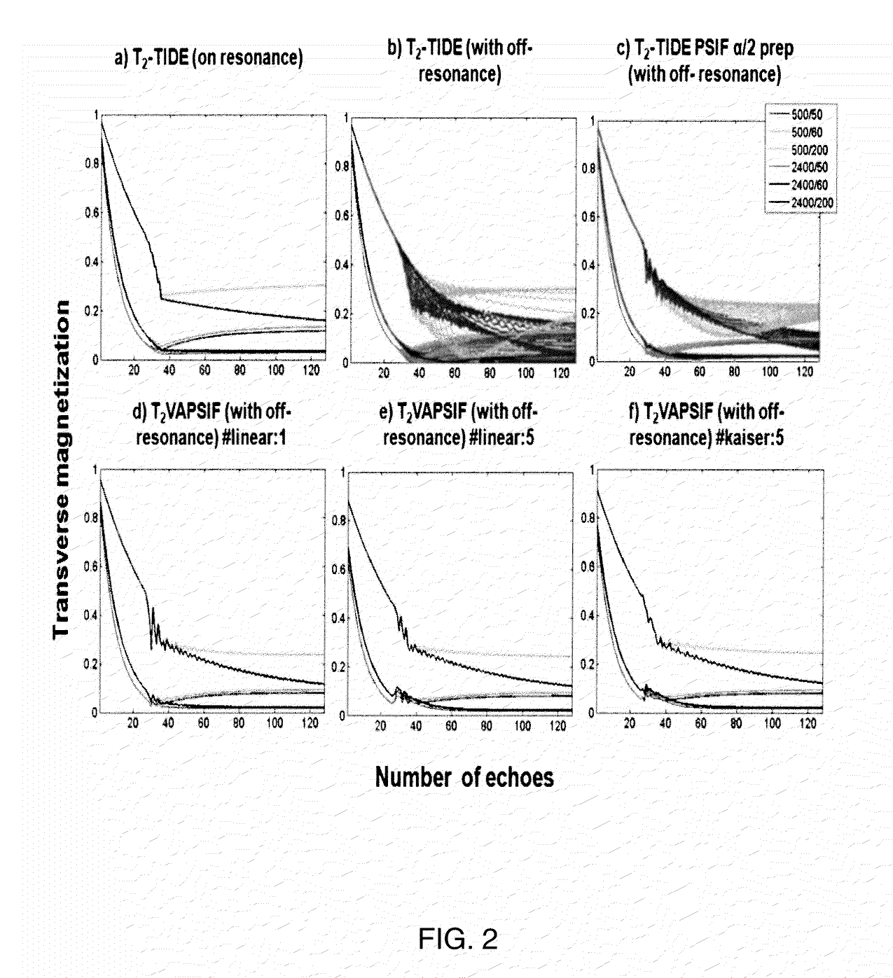

FIG. 2 shows the MATLAB (matrix laboratory) simulation of the normalized transverse magnetization (M_{xy}) over the number of echoes for T₂-TIDE and T₂VAPSIF in the presence of off-resonance and different preparation schemes (α/2 or KB or linear preparation). In all six simulations, the following parameters were used: #M: 0, #N: 25, #nTIDE: 10. SSFP flip angle: 70° and TR: 5.2 ms. TR may refer to the time between successive RF pulses. Six different T₁ and T₂ combinations were used in this simulation (T₂'s of the first three tissues were 50, 60 and 200 ms with T₁ of 500 ms. The second three tissues had the same T₂ values but T₁ was 2400 ms). The off-resonance dephasing angle in the simulations of 2b-2f was varied from −180° to +180°. It can be seen that using b-SSFP (2b) of T₂-TIDE with α/2 preparation pulses (2c) results in nulling of the M_{xy} which would cause banding artifacts in the resulting images.

However, T₂VAPSIF (PSIF acquisition with linear preparation #linear: 1 (2d), #linear: 5 (2e) and KB preparation #kaiser: 5 (2f)) does not result in the nulling of the M_{xy}. Hence, this type of acquisition with KB type preparation, 180° pulses ramped down to a lower flip angle with PSIF acquisition is a robust method in the presence of B₀ inhomogeneities.

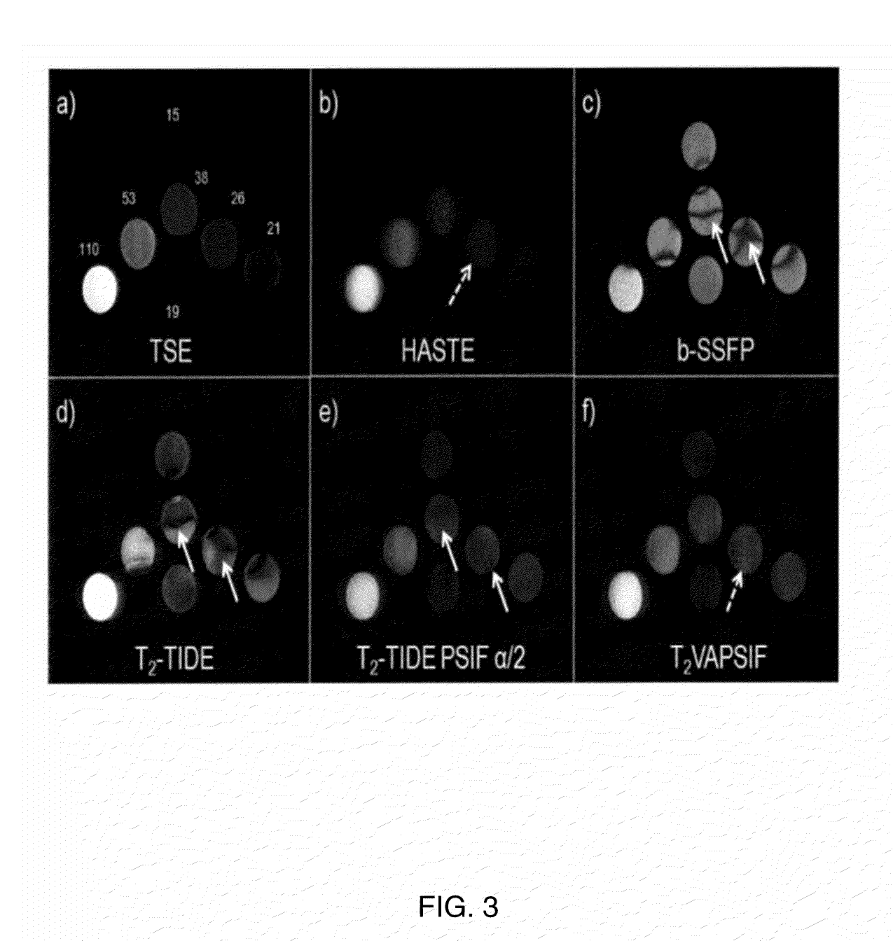

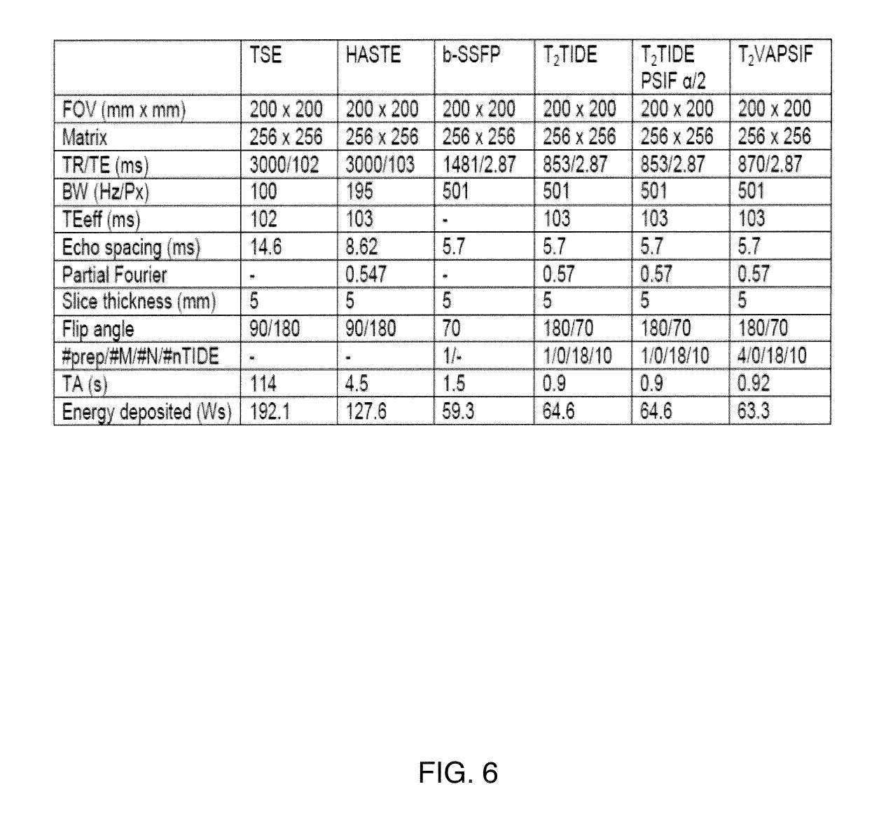

FIG. 3 shows phantom images acquired on a 3T MRI scanner. The imaging parameters are shown in the table of FIG. 6. A phantom was prepared with tubes containing different concentrations of MnCl₂. The T₂ values (in ms) of the MnCl₂ concentrations were measured using a T₂ mapping sequence and are displayed in FIG. 3a. The HASTE image (FIG. 3b) shows edge blurring especially for the shorter T₂ phantoms. This is due to the saturation of the signal during the acquisition of outer k-space lines. The T₂-TIDE image shown in FIG. 3d depicts T₂ weighting; however, it has prominent banding artifacts due to off-resonance similar to the b-SSFP acquisition shown in FIG. 3c. FIG. 3f shows T₂VAPSIF with T₂ weighting similar to HASTE and T₂-TIDE. Furthermore, T₂VAPSIF depicts sharper edges as compared to HASTE and has no off-resonance effects.

The energy deposited and the acquisition durations of different sequences used in the phanto aging are shown in the table of FIG. 6. Thus, from FIGS. 3 and 6 it can be deduced that the T₂VAPSIF shows similar SAR and acquisition duration compared to T₂-TIDE, but is robust in the presence of B₀ inhomogeneities.

In further detail, in FIG. 3, the T₂ values of the phantom probes are indicated in a) TSE sequence, b) HASTE shows poor edge response especially for lower T₂ phantoms. c) b-SSFP and d) T₂-TIDE show banding artifacts due to B₀ inhomogeneities. e) T₂-TIDE PSIF with α/2 preparation has off-resonance related artifacts in the central phantom (indicated by solid arrows). f) T₂VAPSIF provides good T₂ weighting comparable to HASTE and TSE in the presence of inhomogeneities and also has sharper edges (especially for phantoms with lower T₂ values shown by dashed arrows).

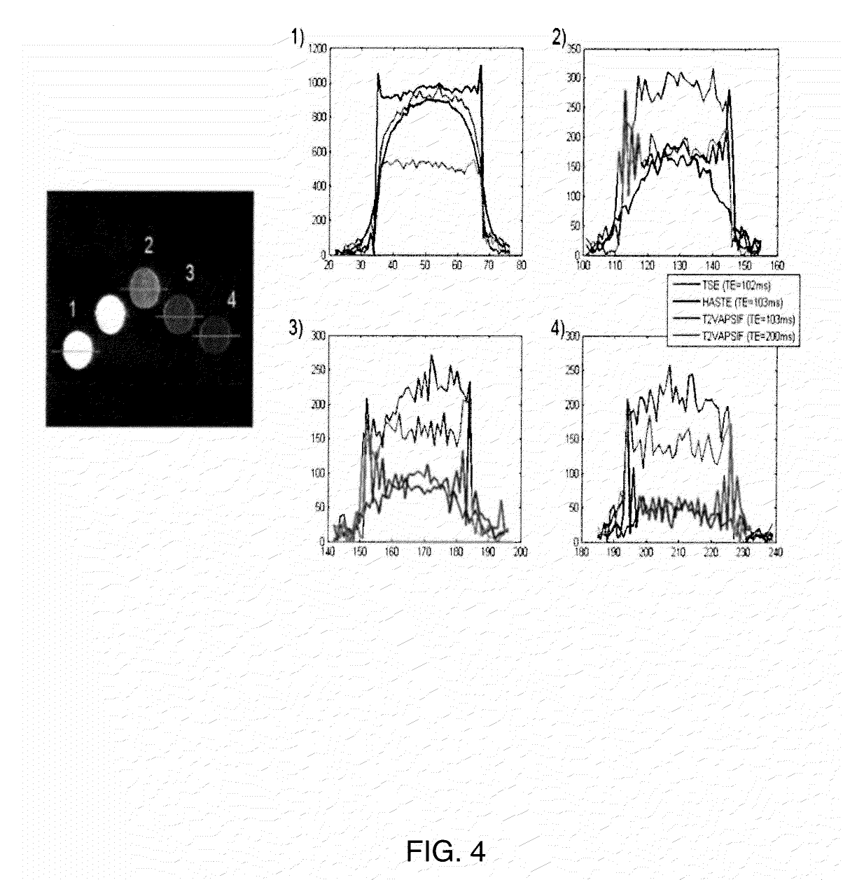

The point spread function (PSF) was calculated for four different T₂ phantoms. FIG. 4 shows that the PSF of T₂VAPSIF is comparable to TSE and better than HASTE (especially for lower T₂ tissues), due to the non-saturation of the signal during the acquisition of outer k-space lines.

In further detail, FIG. 4 is the comparison of the PSF of TSE, HASTE and T₂VAPSIF with two different effective TE_{eff} values of 103 and 200 ms. The PSF of T₂VAPSIF is comparable to the TSE in 3) and 4) and much better than HASTE. In 1) and 2), T₂VAPSIF is better than HASTE but poorer than TSE. This could be due to blurring from partial fourier reconstruction.

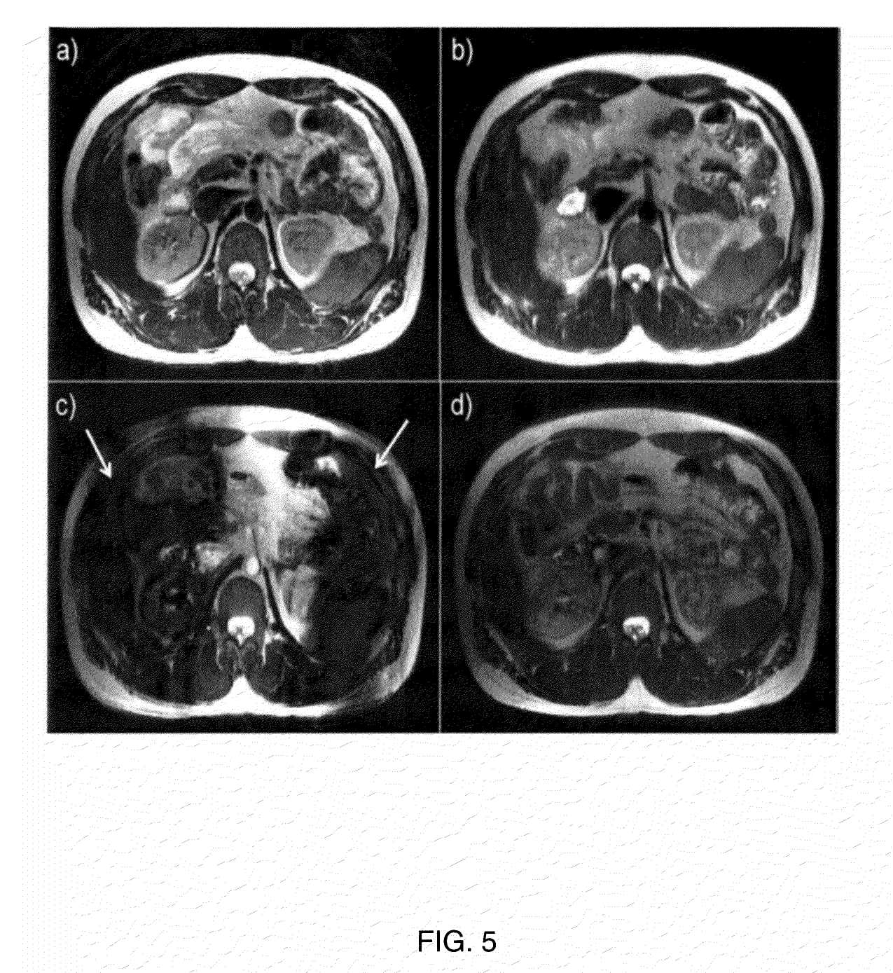

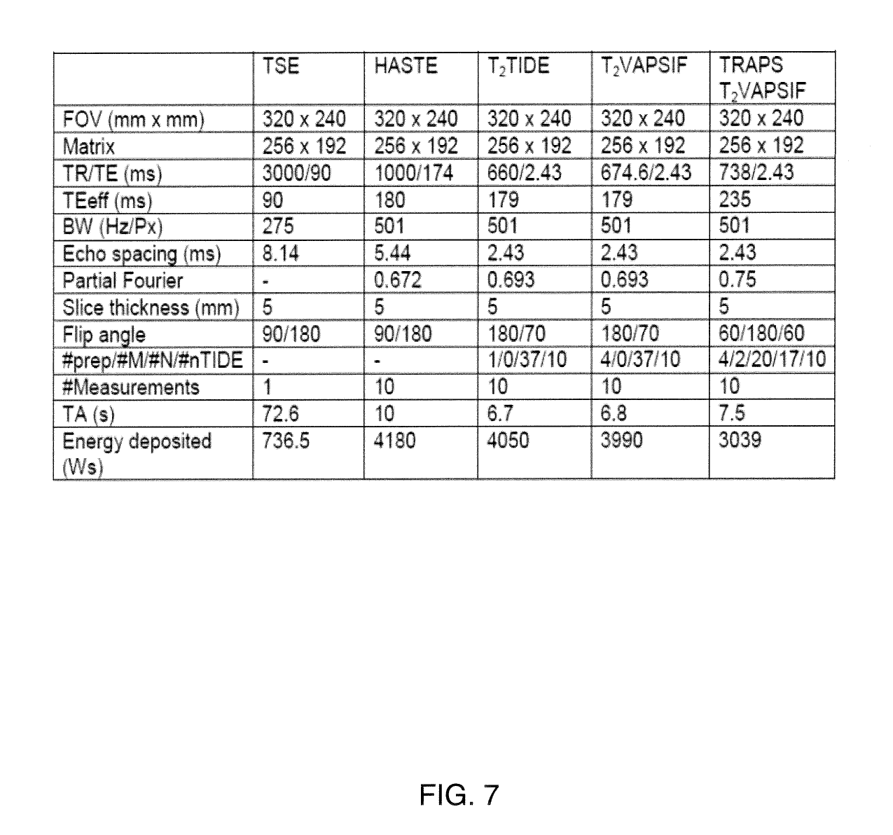

FIG. 5 shows abdominal images of a healthy volunteer acquired using a) TSE, b) HASTE, c) T₂-TIDE and d) T₂VAPSIF. The imaging parameters of the acquisition are shown in the table of FIG. 7. To demonstrate the effect of T₂VAPSIF in the presence of B₀ inhomogeneities, a gradient of 50 μT/m was applied along the read direction. This resulted in banding artifacts in T₂-TIDE as shown in FIG. 5c. FIG. 5d shows an image of T₂VAPSIF with no banding artifacts even in the presence of inhomogeneities.

In further detail, in FIG. 5, a) is the respiratory gated TSE sequence, b) is the HASTE sequence. A gradient of 50 μT/m was applied along the read (left-right) direction which resulted in the banding artifacts in c) acquired with T₂-TIDE (indicated by solid arrows). d) shows the image acquired with T₂VAPSIF with similar parameters as c) except for the PSIF readout and KB preparation.

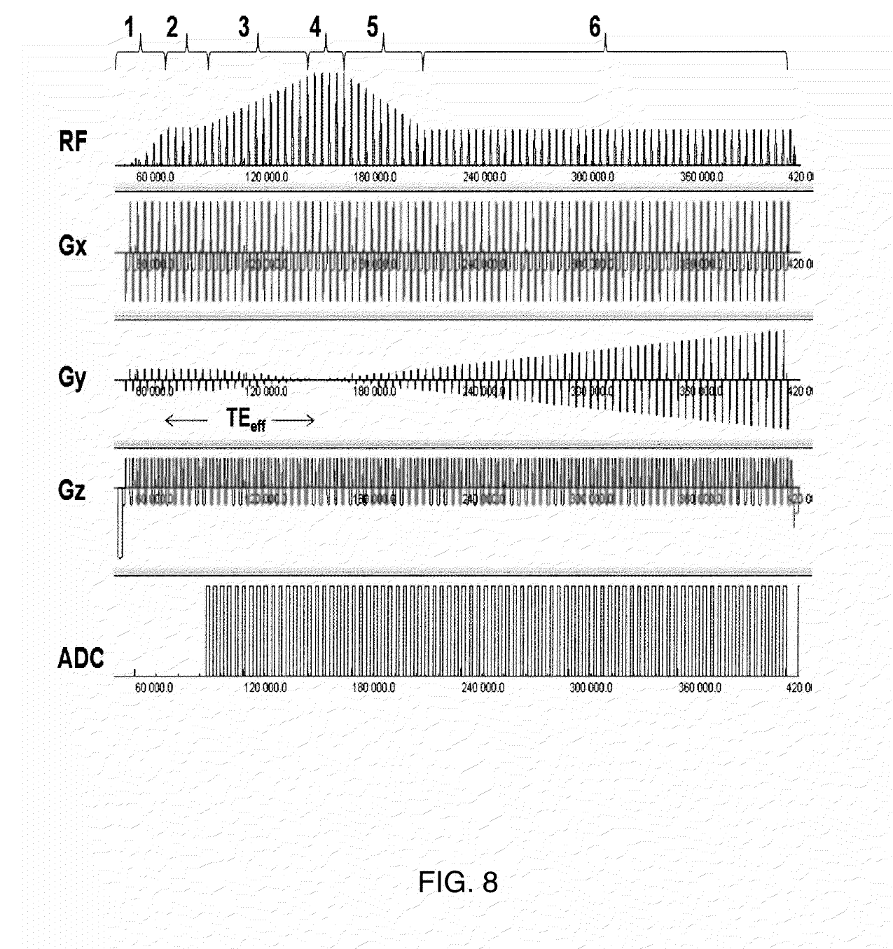

The SAR of the T₂VAPSIF can be reduced further by using a flip angle scheme similar to TRAPS (Transition into Pseudo state), which is a spin echo based sequence. In this TRAPS-based T₂VAPSIF, the variable flip angle consists of six different blocks (i.e., blocks 1-6) as shown in FIG. 8. The first block (1) consists of initial KB like prep pulses #kaiser, followed by a set of lower flip angle pulses #M in block (2). The third block (3) consists of #rampup pulses which ramp up to a 180° flip angle, followed by #plateau 180° pulses (block 4) and #rampdown pulses (block 5) to another lower flip angle (block 6). The center of the k-space is acquired during the #plateau pulses (block 4) and the outer k-space lines are acquired during the sixth block (6) of low flip angle #nSSFP pulses. This has the advantage of reducing the SAR level as the number of 180° pulses is reduced.

The RF, Gx, Gy, Gz and ADC notations in FIG. 8 are the same as those in FIG. 1A.

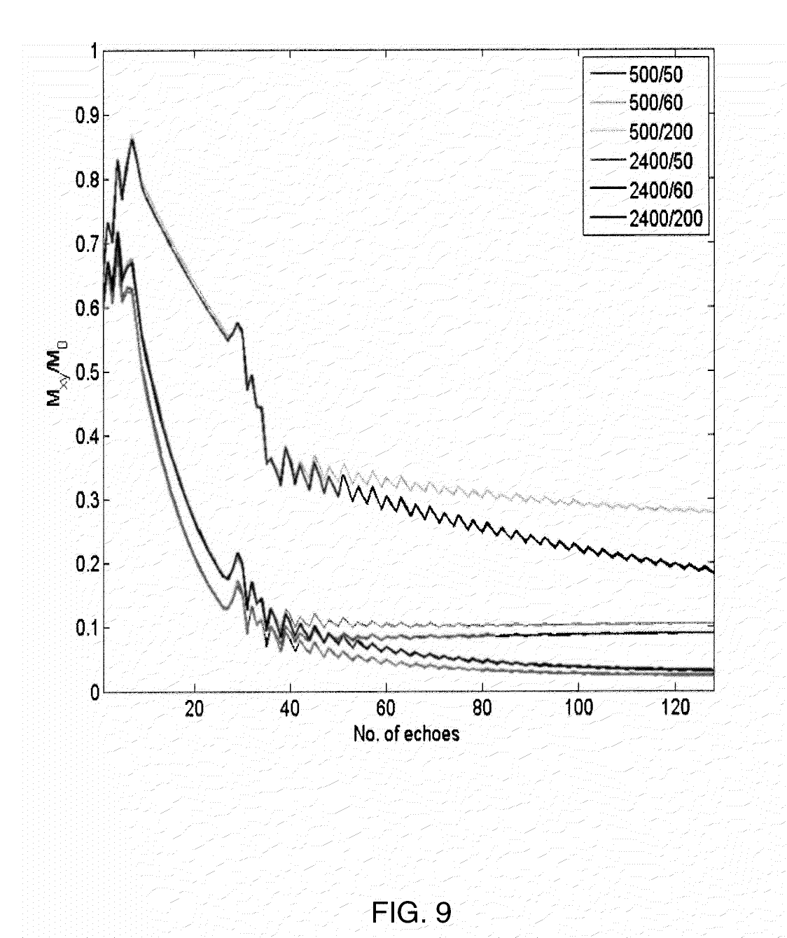

FIG. 9 shows the M_{xy} as a function of the number of echoes for the TRAPS-based T₂VAPSIF. The simulation parameters used for the TRAPS-based T₂VAPSIF were #kaiser: 4, #M: 0, #rampup: 10, #plateau: 15, #rampdown: 10 pulses, SSFP flip angle: 70° and TR: 5.2 ms. It can be seen that there is pure T₂ decay during the first set of pulses, which level out at a steady state value at the end of the rampdown when using the PSIF sequence.

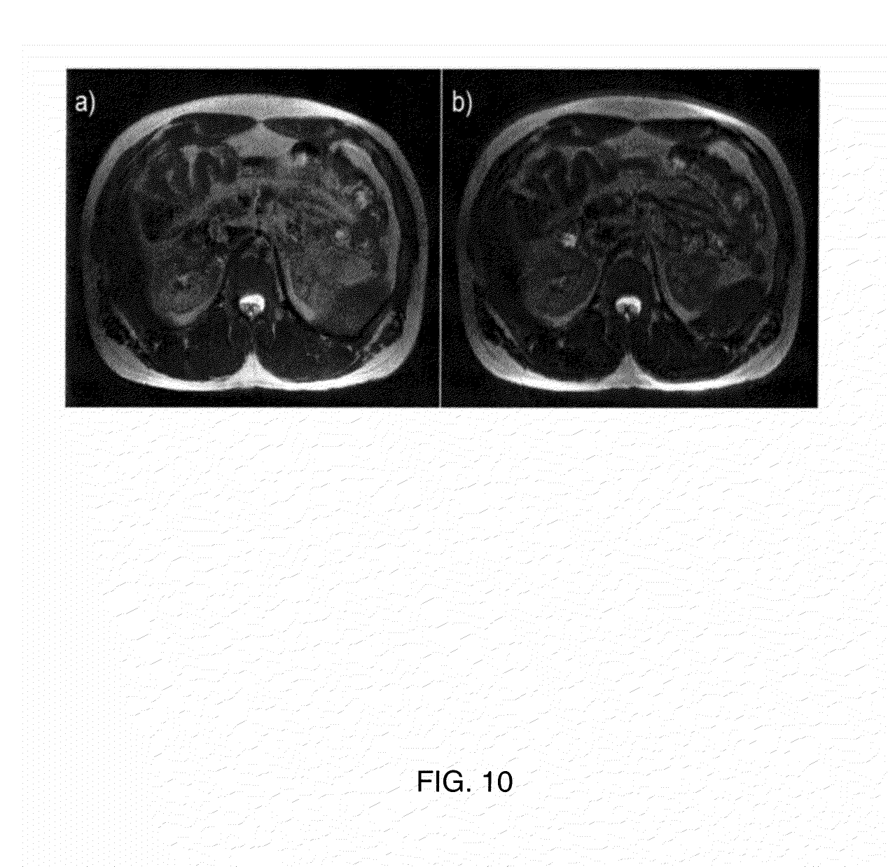

FIG. 10 shows abdominal images acquired using T₂VAPSIF and TRAPS-based T₂VAPSIF. The imaging parameters are shown in the table of FIG. 7. It can be seen that the TRAPS-based T₂VAPSIF provides good T₂ weighting with a 24% decrease in energy deposition for 10 measurements as compared to standard T₂VAPSIF.

The disclosures of Paul D., Markl M., Fautz H. P., Hennig J. “T2-weighted balanced SSFP imaging (T₂-TIDE) using variable flip angles,” Magnetic Resonance in Medicine 2006, July; 56(1): 82-93 and Hennig J., Weigel M., Scheffler K. “Multiecho sequences with variable refocusing flip angles: optimization of signal behavior using smooth transitions between pseudo steady state (TRAPS),” Magnetic Resonance in Medicine 2003, March; 49(3): 527-35 are incorporated by reference herein in their entireties.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article or manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

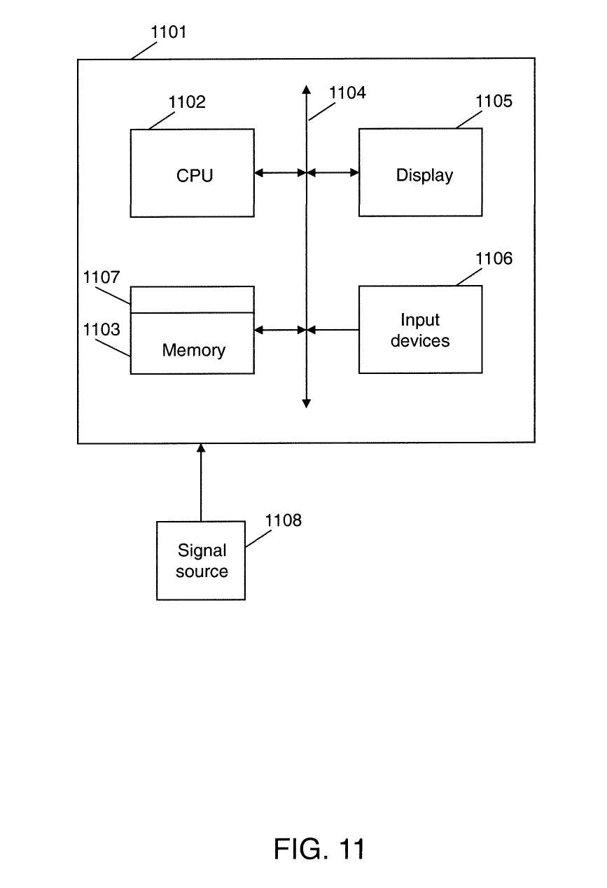

Referring now to FIG. 11, according to an exemplary embodiment of the present invention, a computer system 1101 can comprise, inter alia, a central processing unit (CPU) 1102, a memory 1103 and an input/output (I/O) interface 1104. The computer system 101 is generally coupled through the I/0 interface 1104 to a display 1105 and various input devices 1106 such as a mouse and keyboard. The support circuits can include circuits such as cache, power supplies, clock circuits, and a communications bus. The memory 1103 can include RAM, ROM, disk drive, tape drive, etc., or a combination thereof. Exemplary embodiments of present invention may be implemented as a routine 1107 stored in memory 1103 (e.g., a non-transitory computer-readable storage medium) and executed by the CPU 1102 to process the signal from a signal source 1108. As such, the computer system 1101 is a general-purpose computer system that becomes a specific purpose computer system when executing the routine 1107 of the present invention.

The computer system 1101 also includes an operating system and micro-instruction code. The various processes and functions described herein may either be part of the micro-instruction code or part of the application program (or a combination thereof) which is executed via the operating system. In addition, various other peripheral devices may be connected to the computer system 1101 such as an additional data storage device and a printing device.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described to best explain the principles of the invention and the practical application, and to enable others of ordinary skill in the art to understand the invention for various embodiments with various modifications as are suited to the particular use contemplated.

What is claimed is:

1. A method for acquiring medical images, comprising:
applying, during a first period, a plurality of radio frequency (RF) pulses o an area of interest, wherein the RF pulses applied during the first period are Kaiser-Bessel pulses;
applying, during a second period, a plurality of 180 degree RF preparation pulses to the area;
applying, during a third period, a plurality of 180 degree RF pulses to the area to acquire a center of a k-space;
applying, during a fourth period, a plurality of RF pulses to the area, wherein the RF pulses applied during the fourth period have an angle smaller than the 180 degree RF pulses applied during the third period;
applying, during a fifth period, a plurality of constant RF pulses to the area to acquire outer lines of the k-space, wherein the RF pulses applied during the fifth period have an angle less than the angle of the RF pulses applied during the fourth period; and
generating an image of the area by using a steady-state free precession echo readout.

2. The method of claim 1, wherein the image is a magnetic resonance image.

3. The method of claim 1, wherein the RF pulses of the first to fifth periods are generated by controlling an RF coil array adapted to produce a plurality of magnetic fields in the area.

4. The method of claim 1, wherein the area of interest includes an anatomical part of a human.

5. The method of claim 1, wherein the image is T₂ weighted.

6. The method of claim 1, wherein the steady-state free precession echo readout begins after the second period.

7. A method for acquiring medical images, comprising:
applying, during a first period, a plurality of radio frequency (RF) pulses to an area of interest, wherein the RF pulses applied during the first period are Kaiser-Bessel pulses;
applying, during a second period, a plurality of 180 degree RF pulses to the area to acquire a center of a k-space;
applying, during a third period, a plurality of RF pulses to the area, wherein the RF pulses applied during the third period have an angle smaller than the 180 degree RF pulses applied during the second period;
applying, during a fourth period, a plurality of constant RF pulses to the area to acquire outer lines of the k-space, wherein the RF pulses applied during the fourth period have an angle less than the angle of the RF pulses applied during the third period; and
generating an image of the area by using a steady-state free precession echo readout.

8. The method of claim 7, wherein the image is a magnetic resonance image.

9. The method of claim 7, wherein the RF pulses of the first to fourth periods are generated by controlling an RF coil array adapted to produce a plurality of magnetic fields in the area.

10. The method of claim 7, wherein the area of interest includes an anatomical part of a human.

11. The method of claim 7, wherein the image is T₂ weighted.

12. The method of claim 7, wherein the steady-state free precession echo readout begins after the first period.

13. A method for acquiring medical images, comprising:
applying, during a first period, a plurality of radio frequency (RF) pulses to an area of interest, wherein the RF pulses applied during the first period are linear ramp type pulses;
applying, during a second period, a plurality of 180 degree RF pulses to the area to acquire a center of a k-space;
applying, during a third period, a plurality of RF pulses to the area, wherein the RF pulses applied during the third period have an angle smaller than the 180 degree RF pulses applied during the second period;
applying, during a fourth period, a plurality of constant RF pulses to the area to acquire outer lines of the k-space, wherein the RF pulses applied during the fourth period have an angle less than the angle of the RF pulses applied during the third period; and
generating an image of the area by using a steady-state free precession echo readout.

14. The method of claim 13, wherein the image is a magnetic resonance image.

15. The method of claim 13, wherein the RF pulses of the first to fourth periods are generated by controlling an RF coil array adapted to produce a plurality of magnetic fields in the area.

16. The method of claim 13, wherein the area of interest includes an anatomical part of a human.

17. The method of claim 13, wherein the image is T₂ weighted.

18. The method of claim 13, wherein the steady-state free precession echo readout begins after the first period.

19. A method for acquiring medical images, comprising:
applying, during a first period, a plurality of radio frequency (RF) pulses to an area of interest, wherein the RF pulses applied during the first period are Kaiser-Bessel pulses;
applying, during a second period, a plurality of RF pulses to the area, wherein the RF pulses applied during the second period have an angle greater than an angle of the Kaiser-Bessel pulses applied during the first period;
applying, during a third period, a plurality of RF pulses to the area, wherein the RF pulses applied during the third period ramp up the angle of the RF pulses applied during the second period to about 180 degrees;
applying, during a fourth period, a plurality of 180 degree RF pulses to the area to acquire a center of a k-space;
applying, during a fifth period, a plurality of RF pulses to the area, wherein the RF pulses applied during the fifth period have an angle smaller than the 180 degree RF pulses applied during the fourth period;
applying, during a sixth period, a plurality of constant RF pulses to the area to acquire outer lines of the k-space, wherein the RF pulses applied during the sixth period have an angle less than the angle of the RF pulses applied during the fifth period; and
generating an image of the area by using a steady-state free precession echo readout.

20. The method of claim 19, wherein the steady-state free precession echo readout begins after the second period.
